(19) United States
(12) Patent Application Publication
(10) Pub. No.: US 2022/0137112 A1
(43) Pub. Date: May 5, 2022

(54) ALIGNMENT OF SYNCHRONIZED PHASE ANGLE MEASUREMENTS WITH PRESENCE OF PRACTICAL TIME SHIFT

(71) Applicant: University of Tennessee Research Foundation, Knoxville, TN (US)

(72) Inventors: Yilu LIU, Knoxville, TN (US); Wenxuan YAO, Knoxville, TN (US); He YIN, Knoxville, TN (US); Wenpeng YU, Knoxville, TN (US)

(21) Appl. No.: 17/085,526

(22) Filed: Oct. 30, 2020

(51) Int. Cl. G01R 25/04; G01R 29/18; H02J 3/00

(52) U.S. Cl. CPC G01R 25/04; H02J 2203/20; H02J 3/001; G01R 29/18

(57) ABSTRACT

A method includes performing by a processor: determining a phase angle alignment parameter based on a ratio of a phase angle difference and a frequency difference, the phase angle difference comprising a difference between a first phase angle corresponding to a reference synchronized measurement device (SMD) and a second phase angle corresponding to a follower SMD, the frequency difference comprising a difference between a frequency at which the first and second phase angles are measured and a nominal frequency; receiving a first plurality of synchrophasor measurements of a power system signal from the reference SMD; receiving a second plurality of synchrophasor measurements of the power system signal from the follower SMD, the first plurality of synchrophasor measurements and the second plurality of synchrophasor measurements being offset in time relative to each other by a sampling time shift; and aligning phase angles of the second plurality of synchrophasor measurements with phase angles of the first plurality of synchrophasor measurements using the phase angle alignment parameter.

### STATEMENT REGARDING FEDERALLY SPONSORED RESEARCH OR DEVELOPMENT

This invention was made with government support under contract number NSF EEC-1041877 awarded by the National Science Foundation. The government has certain rights in the invention.

### BACKGROUND

The present disclosure relates to power systems, and, in particular, to monitoring, operation, and control of power systems.

Synchronized Phase Angle Measurement (SPAM) estimated from Synchronized Measurement Devices (SMD) may contribute substantially to power system applications, such as event detection and islanding detection. To achieve high-precision in synchronization between different SMDs, the SMDs may obtain Pulse Per Second Signal (PPS) in nanosecond accuracy from Global Positioning System (GPS) receivers for waveform sampling and then timestamp calculated SPAM data with a UTC time index before transmitting the SPAM data to a Phasor Data Concentrator (PDC), where the SPAM data may be unwrapped and aligned before being provided to various analytical applications.

When SMDs are used in practice, however, due to several uncontrollable factors, a time shift may exist between SMDs manufactured by various vendors, which may lead to unexpected angle drift, which in turn may aversely influence the SPAM alignment in a PDC. Moreover, as SPAM may be calculated via Discrete Fourier Transform (DFT) according to the IEEE C37 standard, different window sizes and sampling rates may be used for different commercial SMDs, which may worsen the issue of angle drift, especially under the condition of off-nominal frequency. According to the IEEE C37 standard, an angle drift greater than 0.57° corresponding to a 26 μs time shift may cause the total vector error to exceed a 1% limit.

A time shift detection method may include a similarity analysis between relative phase angle and frequency. However, such an approach may not be able to correct angle drifts less than 0.57° in real-time. Applications that rely on SPAM may be vulnerable to this inaccurate alignment. The inaccuracy may, for example, result in one or more false event triggers.

### SUMMARY

In some embodiments of the inventive concept, a method comprises determining a phase angle alignment parameter based on a ratio of a phase angle difference and a frequency difference, the phase angle difference comprising a difference between a first phase angle corresponding to a reference synchronized measurement device (SMD) and a second phase angle corresponding to a follower SMD, the frequency difference comprising a difference between a frequency at which the first and second phase angles are measured and a nominal frequency; receiving a first plurality of synchrophasor measurements of a power system signal from the reference SMD; receiving a second plurality of synchrophasor measurements of the power system signal from the follower SMD, the first plurality of synchrophasor measurements and the second plurality of synchrophasor measurements being offset in time relative to each other by a sampling time shift; and aligning phase angles of the second plurality of synchrophasor measurements with phase angles of the first plurality of synchrophasor measurements using the phase angle alignment parameter.

In other embodiments, determining the phase angle alignment parameter comprises averaging the ratio of the phase angle difference and the frequency difference over a plurality of frequencies at which the first and second phase angles are measured.

In still other embodiments, the plurality of frequencies are in a range between the nominal frequency and the nominal frequency plus 2 Hz.

In still other embodiments, the nominal frequency is about 60 Hz.

In still other embodiments, a manufacturer of the reference SMD is different than a manufacturer of the follower SMD.

In still other embodiments, aligning phase angles of the second plurality of synchrophasor measurements with phase angles of the first plurality of synchrophasor measurements comprises determining an offset for each of the second plurality of synchrophasor measurements, the offset comprising a product of the phase angle alignment parameter and a difference between a frequency corresponding to the respective one of the second plurality of synchrophasor measurements and the nominal frequency; and adding the plurality of offsets to the phase angles of the second plurality of synchrophasor measurements, respectively.

In still other embodiments, the method further comprises managing operation of one or more components of the power system based on the first plurality of synchrophasor measurements from the reference SMD and the second plurality of synchrophasor measurements from the follower SMD.

In some embodiments of the inventive concept, a system comprises a processor; and a memory coupled to the processor and comprising computer readable program code embodied in the memory that is executable by the processor to perform operations comprising: determining a phase angle alignment parameter based on a ratio of a phase angle difference and a frequency difference, the phase angle difference comprising a difference between a first phase angle corresponding to a reference synchronized measurement device (SMD) and a second phase angle corresponding to a follower SMD, the frequency difference comprising a difference between a frequency at which the first and second phase angles are measured and a nominal frequency; receiving a first plurality of synchrophasor measurements of a power system signal from the reference SMD; receiving a second plurality of synchrophasor measurements of the power system signal from the follower SMD, the first plurality of synchrophasor measurements and the second plurality of synchrophasor measurements being offset in time relative to each other by a sampling time shift; and aligning phase angles of the second plurality of synchrophasor measurements with phase angles of the first plurality of synchrophasor measurements using the phase angle alignment parameter.

In further embodiments, determining the phase angle alignment parameter comprises averaging the ratio of the phase angle difference and the frequency difference over a plurality of frequencies at which the first and second phase angles are measured.

In still further embodiments, the plurality of frequencies are in a range between the nominal frequency and the nominal frequency plus 2 Hz.

In still further embodiments, the nominal frequency is about 60 Hz.

In still further embodiments, a manufacturer of the reference SMD is different than a manufacturer of the follower SMD.

In still further embodiments, aligning phase angles of the second plurality of synchrophasor measurements with phase angles of the first plurality of synchrophasor measurements comprises determining an offset for each of the second plurality of synchrophasor measurements, the offset comprising a product of the phase angle alignment parameter and a difference between a frequency corresponding to the respective one of the second plurality of synchrophasor measurements and the nominal frequency; and adding the plurality of offsets to the phase angles of the second plurality of synchrophasor measurements, respectively.

In still further embodiments, the operations further comprise managing operation of one or more components of the power system based on the first plurality of synchrophasor measurements from the reference SMD and the second plurality of synchrophasor measurements from the follower SMD.

In some embodiments of the inventive concept, a computer program product comprises a non-transitory computer readable storage medium comprising computer readable program code embodied in the medium that is executable by a processor to perform operations comprising determining a phase angle alignment parameter based on a ratio of a phase angle difference and a frequency difference, the phase angle difference comprising a difference between a first phase angle corresponding to a reference synchronized measurement device (SMD) and a second phase angle corresponding to a follower SMD, the frequency difference comprising a difference between a frequency at which the first and second phase angles are measured and a nominal frequency; receiving a first plurality of synchrophasor measurements of a power system signal from the reference SMD; receiving a second plurality of synchrophasor measurements of the power system signal from the follower SMD, the first plurality of synchrophasor measurements and the second plurality of synchrophasor measurements being offset in time relative to each other by a sampling time shift; and aligning phase angles of the second plurality of synchrophasor measurements with phase angles of the first plurality of synchrophasor measurements using the phase angle alignment parameter.

In other embodiments, determining the phase angle alignment parameter comprises averaging the ratio of the phase angle difference and the frequency difference over a plurality of frequencies at which the first and second phase angles are measured.

In still other embodiments, the plurality of frequencies are in a range between the nominal frequency and the nominal frequency plus 2 Hz.

In still other embodiments, the nominal frequency is about 60 Hz.

In still other embodiments, aligning phase angles of the second plurality of synchrophasor measurements with phase angles of the first plurality of synchrophasor measurements comprises determining an offset for each of the second plurality of synchrophasor measurements, the offset comprising a product of the phase angle alignment parameter and a difference between a frequency corresponding to the respective one of the second plurality of synchrophasor measurements and the nominal frequency; and adding the plurality of offsets to the phase angles of the second plurality of synchrophasor measurements, respectively.

In still other embodiments, the operations further comprise managing operation of one or more components of the power system based on the first plurality of synchrophasor measurements from the reference SMD and the second plurality of synchrophasor measurements from the follower SMD.

Other methods, systems, articles of manufacture, and/or computer program products, according to embodiments of the inventive concept, will be or become apparent to one with skill in the art upon review of the following drawings and detailed description. It is intended that all such additional systems, methods, articles of manufacture, and/or computer program products be included within this description, be within the scope of the present inventive concept, and be protected by the accompanying claims.

### BRIEF DESCRIPTION OF THE DRAWINGS

Other features of embodiments will be more readily understood from the following detailed description of specific embodiments thereof when read in conjunction with the accompanying drawings, in which:

FIG. 1 is a block diagram that illustrates a power distribution network including a phase angle alignment of Synchronized Phase Angel Measurement (SPAM) data capability in accordance with some embodiments of the inventive concept;

FIG. 2 illustrates a data processing system that may be used to implement a Distribution Management System (DMS) processor associated with a power system of FIG. 1 in accordance with some embodiments of the inventive concept;

FIG. 3 is a block diagram that illustrates a software/hardware architecture for use in a DMS processor for aligning phase angles of SPAM data generated by multiple Synchronized Measurement Devices (SMDs) in accordance with some embodiments of the inventive concept;

FIGS. 4-5 are flowcharts that illustrate operations for aligning phase angles of SPAM data generated by multiple Synchronized Measurement Devices (SMDs) in accordance with some embodiments of the inventive concept;

FIG. 6 is a graph of a frequency ramp profile used to estimate a phase angle alignment parameter or coefficient according to some embodiments of the inventive concept;

FIG. 7 is a graph of relative phase angles between SMDs in a laboratory experiment in accordance with some embodiments of the inventive concept;

FIG. 8 is a graph of aligned phase angles between SMDs in the laboratory experiment in accordance with some embodiments of the inventive concept;

FIG. 9 is a graph of relative phase angles between SMDs in a field test in accordance with some embodiments of the inventive concept; and

FIG. 10 is a graph of aligned phase angles between SMDs in the field test in accordance with some embodiments of the inventive concept.

### DETAILED DESCRIPTION

In the following detailed description, numerous specific details are set forth to provide a thorough understanding of embodiments of the present disclosure. However, it will be understood by those skilled in the art that the present invention may be practiced without these specific details. In some instances, well-known methods, procedures, components and circuits have not been described in detail so as not to obscure the present disclosure. It is intended that all embodiments disclosed herein can be implemented separately or combined in any way and/or combination. Aspects described with respect to one embodiment may be incorporated in different embodiments although not specifically described relative thereto. That is, all embodiments and/or features of any embodiments can be combined in any way and/or combination.

As used herein, the term “data processing facility” includes, but it is not limited to, a hardware element, firmware component, and/or software component. A data processing system may be configured with one or more data processing facilities.

Synchronized Measurement Devices (SMDs) are devices that are used to estimate the magnitude and phase angle of the voltage or current in a power system using a common time source for synchronization. SMDs are increasingly deployed in power systems in to provide synchronized measurements for system situational awareness and observation of behavioral dynamics. The SMDs may be placed in various locations within a power system including the main power grid, the distribution grid, and/or consumer locations. SMDs may be used to collect samples from a waveform in quick succession and to reconstruct the phasor quantity, which is made up of an angle measurement and a magnitude measurement known as a synchrophasor measurement.

Some embodiments of the inventive concept stem from a realization that, in practice, a time shift may exist between SMDs manufactured by different vendors, which can result in unexpected angle drift. This may adversely affect the alignment of Synchronized Phase Angle Measurement (SPAM) data collected, for example, by way of a Phasor Data Concentrator (PDC), from the various SMDs in a power system. As a result, the applications that use the SPAM data may generate inaccurate outputs, reach inaccurate conclusions, and may trigger unneeded/improper actions or fail to trigger actions that are needed in maintaining a power system, for example. Some embodiments of the inventive concept may rectify the angle difference among SMDs in a power system and mitigate the adverse impact of the inevitable time drift between the SMDs.

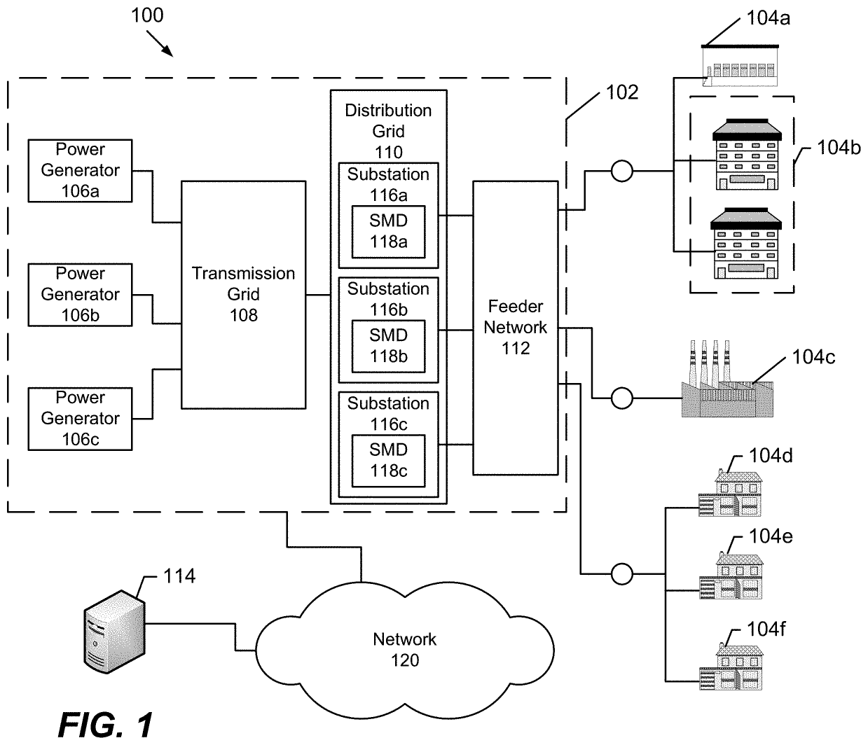

Referring to FIG. 1, a power system distribution network 100 including a phase angle alignment of SPAM data capability, in accordance with some embodiments of the inventive concept, comprises a main power grid 102, which is typically operated by a public or private utility, and which provides power to various power consumers 104a, 104b, 104c, 104d, 104e, and 104f. The electrical power generators 106a, 106b, and 106c are typically located near a fuel source, at a dam site, and/or at a site often remote from heavily populated areas. The power generators 106a, 106b, and 106c may be nuclear reactors, coal burning plants, hydroelectric plants, and/or other suitable facility for generating bulk electrical power. The power output from the power generators 106, 106b, and 106c is carried via a transmission grid or transmission network over potentially long distances at relatively high voltage levels. A distribution grid 110 may comprise multiple substations 116a, 116b, 116c, which receive the power from the transmission grid 108 and step the power down to a lower voltage level for further distribution. A feeder network 112 distributes the power from the distribution grid 110 substations 116a, 116b, 116c to the power consumers 104a, 104b, 104c, 104d, 104e, and 104f. The power substations 116a, 116b, 116c in the distribution grid 110 may step down the voltage level when providing the power to the power consumers 104a, 104b, 104c, 104d, 104e, and 104f through the feeder network 112.

As shown in FIG. 1, the power consumers 104a, 104b, 104c, 104d, 104e, and 104f may include a variety of types of facilities including, but not limited to, a warehouse 104a, a multi-building office complex 104b, a factory 104c, and residential homes 104d, 104e, and 104f. A feeder circuit may connect a single facility to the main power grid 102 as in the case of the factory 104c or multiple facilities to the main power grid 102 as in the case of the warehouse 104a and office complex 104b and also residential homes 104d, 104e, and 104f. Although only six power consumers are shown in FIG. 1, it will be understood that a feeder network 112 may service hundreds or thousands of power consumers.

The power distribution network 100 further comprises a Distribution Management System (DMS) 114, which may monitor and control the generation and distribution of power via the main power grid 102. The DMS 114 may comprise a collection of processors and/or servers operating in various portions of the main power grid 102 to enable operating personnel to monitor and control the main power grid 102. The DMS 114 may further include other monitoring and/or management systems for use in supervising the main power grid 102. One such system is known as the Supervisory Control and Data Acquisition (SCADA) system, which is a control system architecture that uses computers, networked data communications, and graphical user interfaces for high-level process supervisory management of the main power grid. The DMS 114 may further include a phasor data concentrator module that is configured to manage the reception and processing of SPAM data from the SMDs 118a, 118b, and 118c. The phasor data concentrator module may cooperate with other supervisory, monitoring, and control modules, systems, and/or capabilities provided via the DMS 114

According to some embodiments of the inventive concept, SMDs 118a, 118b, and 118c may be located at the substations 116a, 116b, and 116c, respectively. SMDs 118a, 118b, and 118c may measure current and voltage by amplitude and phase at selected stations of the distribution grid 110. SMDs 118a, 118b, and 118c may also be used to measure and/or compute other data/information, such as power quality factors. Using, for example, Global Positioning System (GPS) information, the SMDs 118a, 118b, and 118c may be associated with specific geographic locations. Moreover, high-precision time synchronization, according to some embodiments of the inventive concept may allow comparing measured values (synchrophasors) from different substations distant to each other and drawing conclusions regarding the system state and dynamic events, such as power swing conditions, forced oscillation events, and the like. The SMDs 118a, 118b, 118c may determine current and voltage phasors, frequency, and rate of change of frequency and provide these measurements with time stamps for transmittal to the DMS 114 for analysis. The SMDs 118a, 118b, 118c may communicate with the DMS 114 over the network 120. The network 120 may be a global network, such as the Internet or other publicly accessible network. Various elements of the network 120 may be interconnected by a wide area network, a local area network, an Intranet, and/or other private network, which may not be accessible by the general public. Thus, the communication network 120 may represent a combination of public and private networks or a virtual private network (VPN). The network 120 may be a wireless network, a wireline network, or may be a combination of both wireless and wireline networks. Although the SMDs 118a, 118b, and 118c are shown as being located in the substations 116a, 116b, and 116c, it will be understood that the SMDs 118a, 118b, and 118c may be located in other locations within the distribution grid 110, within the main power grid 102, or even at consumer locations 104a, 104b, 104c, 104d, 104e, and 104f, such as, for example, in proximity to wall outlets or other power access points.

Although FIG. 1 illustrates an example a power distribution network 100 including a phase angle alignment of SPAM data capability, it will be understood that embodiments of the inventive concept are not limited to such configurations, but are intended to encompass any configuration capable of carrying out the operations described herein.

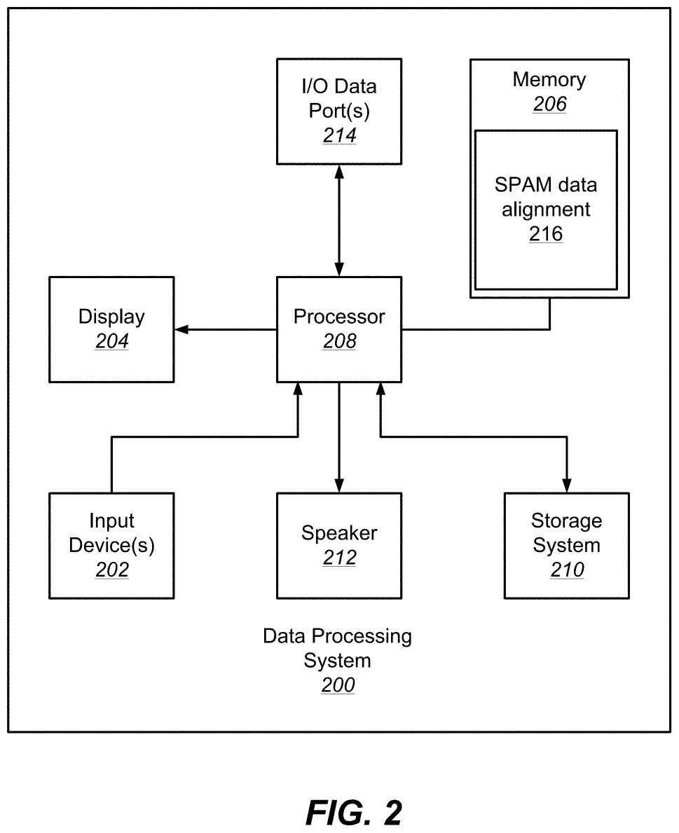

Referring now to FIG. 2, a data processing system 200 that may be used to implement the DMS 114 processor of FIG. 1, in accordance with some embodiments of the inventive concept, comprises input device(s) 202, such as a keyboard or keypad, a display 204, and a memory 206 that communicate with a processor 208. The data processing system 200 may further include a storage system 210, a speaker 212, and an input/output (I/O) data port(s) 214 that also communicate with the processor 208. The storage system 210 may include removable and/or fixed media, such as floppy disks, ZIP drives, hard disks, or the like, as well as virtual storage, such as a RAMDISK. The I/O data port(s) 214 may be used to transfer information between the data processing system 200 and another computer system or a network (e.g., the Internet). These components may be conventional components, such as those used in many conventional computing devices, and their functionality, with respect to conventional operations, is generally known to those skilled in the art. The memory 206 may be configured with a SPAM data alignment module 216 that may provide functionality that may include, but is not limited to, aligning the synchrophasor measurement phase angles of one or more follower SMDs 118a, 118b, and 118c with a base or reference SMD 118a, 118b, and 118c that may be misaligned as result of time shift between the different SMDs 118a, 118b, and 118c in accordance with some embodiments of the inventive concept. The phase angle aligned synchrophasor measurements from the various SMDs 118a, 118b, and 118c located throughout a power system topology may be used to manage or control the operation of one or more elements or components in the power system. For example, the synchrophasor measurements may be used to detect events, such as droop, nominal frequency (e.g., 60 Hz) deviation based on load, islanding of portions of the power system, and the like.

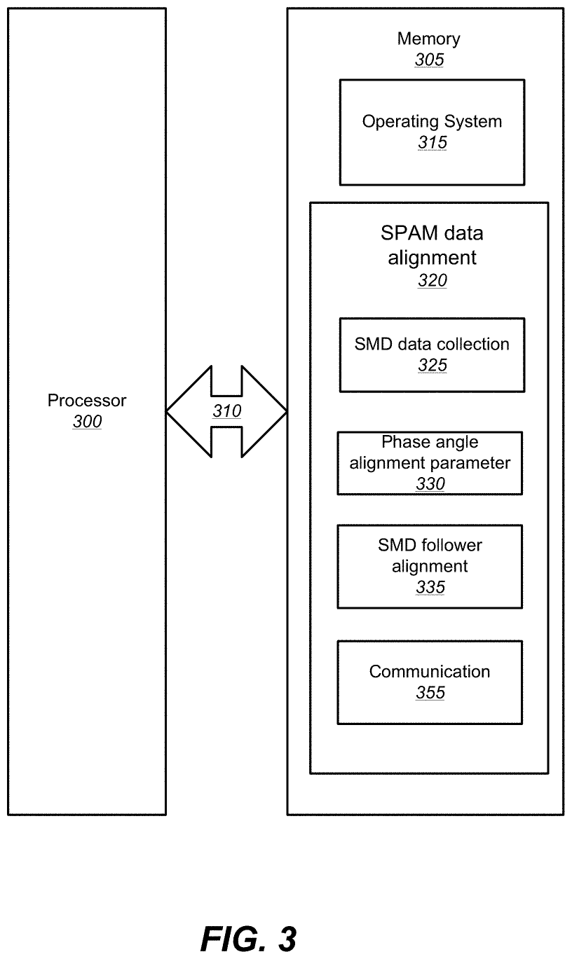

FIG. 3 illustrates a processor 300 and memory 305 that may be used in embodiments of data processing systems, such as the DMS 114 processor of FIG. 1 and the data processing system 200 of FIG. 2, respectively, for aligning phase angles of SPAM data generated by multiple SMDs in accordance with some embodiments of the inventive concept. The processor 300 communicates with the memory 305 via an address/data bus 310. The processor 300 may be, for example, a commercially available or custom microprocessor. The memory 305 is representative of the one or more memory devices containing the software and data used for detecting synchrophasor measurement timestamp time shifts in accordance with some embodiments of the inventive concept. The memory 305 may include, but is not limited to, the following types of devices: cache, ROM, PROM, EPROM, EEPROM, flash, SRAM, and DRAM.

As shown in FIG. 3, the memory 305 may contain two or more categories of software and/or data: an operating system 315 and a forced oscillation source determination module 320. In particular, the operating system 315 may manage the data processing system's software and/or hardware resources and may coordinate execution of programs by the processor 300. The SPAM data alignment module 320 may comprise an SMD data collection module 325, a phase angle alignment parameter module 330, an SMD follower alignment module 335, and a communication module 355.

The SMD data collection module 325 may be configured to receive measured information, such as, for example, time-stamped power system synchrophasor measurements from the SMDs 118a, 118b, and 118c in the distribution grid 110. Each of the synchrophasor measurements of a power system signal may include, but is not limited to, a phase angle, frequency value, and a timestamp associated with the synchrophasor measurement.

The phase angle alignment parameter module 330 may be configured to determine a phase angle alignment parameter based on a ratio of a phase angle difference between a base or reference SMD 118a, 118b, and 118c and a follower SMD 118a, 118b, and 118c and a frequency difference between a frequency at which the phase angles of the reference SMD 118a, 118b, and 118c and the follower SMD 118a, 118b, and 118c were measured and a nominal frequency, e.g., 60 Hz.

The SMD follower alignment module 335 may be configured to align the phase angle of a follower SMD 118a, 118b, and 118c with the phase angle of a reference SMD 118a, 118b, and 118c by determining an offset for the phase angle of the follower SMD 118a, 118b, and 118c and adding the offset to the phase angle of the follower SMD 118a, 118b, and 118c. The offset may be determined as the product of the phase angle alignment parameter determined by the phase angle alignment parameter module 330 and a difference between a frequency at which the phase angle of the follower SMD was measured and a nominal frequency, e.g., 60 Hz.

Operations of the phase angle alignment parameter module 330 and the SMD follower alignment module 335 for compensating for phase angle differences among SMDs 118a, 118b, and 118c due to time shift between the SMDs 118a, 118b, and 118c, according to some embodiments of the inventive concept, will now be described.

The SPAM data reported by SMDs 118a, 118b, and 118c are the phase angle values at the sampling times. Assuming there is an actual reference phase angle measured by one SMD 118a, 118b, and 118c with sampling time Tᵣ, referred as A_{r,a} and an actual phase angle measured by the ith SMD with sampling time Tᵢ, referred as A_{i,a}, A_{r,a} and A_{i,a} may shift relative each other when Tᵣ≠Tᵢ which may occur in practice. The difference between Tᵣ and Tᵢ may be at the millisecond level, which is typically smaller than the reporting interval of an SMD 118a, 118b, and 118c. Thus it may be difficult to be detected through normal data screening. After unwrapping the phase angles, the relationship between A_{r,a} and A_{i,a} can be written as Equation 1:

A_{r,a}=A_{i,a}+2π∫_{T}_{ᵣ}^{T}^{ᵢ}(f−f₀)dt, (1)

where f is the frequency reported in the latest SMD data frame and f0 is the nominal frequency. Considering the time between Tᵣ and Tᵢ is typically far less than the reporting interval, f, can be assumed to be constant and, thus, Equation 1 can be rewritten as Equation 2:

A_{r,a}=A_{i,a}+2π(Tᵣ−Tᵢ)(f−f₀). (2)

Because both SMDs 118a, 118b, and 118c can only get the measured phase angle, the off-nominal frequency has influences on the Discrete Fourier Transform (DFT) based phase angle estimation. The measured phase angle by DFT estimation consists of three components in Equation 3: 1) actual phase angle, A_{i,a}; 2) invariant error; and 3) variant sinusoidal form error through which the measured phase angle by the ith SMD 118a, 118b, and 118c. These components can be expressed in Equation 3 as follows:

$${A}_{i} = {\underbrace{{A}_{i , a}}}_{1 )} + {\underbrace{\frac{( {N}_{i} - 1 ) πΔ f}{{N}_{i} {f}_{0} }}}_{2 )} - {\underbrace{\frac{N Δ f}{2 {f}_{0} + Δ f } sin [ {A}_{i , a} + \frac{( {N}_{i} - 1 ) 2 π ( {f}_{0} + Δ f )}{{N}_{f} {f}_{0} } ]}}_{3 )} , \qquad ( 3 )$$

where Aᵢ is the measured phase angle of the ith SMD 118a, 118b, and 118c; Δf is f−f0; and Ni is the size of the DFT window in the ith SMD 118a, 118b, and 118c. The variant sinusoidal form error can be suppressed in a quasi-positive-sequence DFT algorithm while the invariant error can be canceled out by adding an “offset.” The “offset can be written as Equation 4:

$${offset}_{i} = \frac{( {N}_{i} - 1 ) π ( f + {f}_{0} )}{{N}_{i} {f}_{0} } . \qquad ( 4 )$$

Considering the impact of the varietn sinusoidal form error may be negligible compared with the offset error, the varietn sinusoidal form error maybe ignored so as to simplify Equation 3 as shown below in Equation 5:

Aᵢ≈A_{i,a}+offsetᵢ (5)

Now, by substituting Equation 5 into Equation 2, the A_{r,a} can be computed as Equation 6:

A_{r,a}=Aᵢ−offsetᵢ+2π(Tᵣ−Tᵢ)(f−f₀). (6)

If the “offset” of the reference SMD 118a, 118b, and 118c is also taken into consideration, the measured phase angle of the reference SMD can be written as Equations 7 and 8:

$$\begin{matrix}{A}_{r} = {A}_{i} - {offset}_{i} + {offset}_{r} + 2 π ( {T}_{r} - {T}_{i} ) ( f - {f}_{0} ) , & ( 7 ) \\ {offset}_{r} = \frac{( {N}_{r} - 1 ) π ( f - {f}_{0} )}{{N}_{r} {f}_{0} } , & ( 8 )\end{matrix}$$

where Aᵣ is the measured phase angle of the reference SMD, offsetᵣ is the “offset” of the reference SMD, and Nᵣ is the size of the DFT window in the reference SMD 118a, 118b, and 118c. Because the frequency for two SMDs 118a, 118b, and 118c are assumed to be a constant value between Tᵣ and T_{f} the Aᵣ can be further simplified as Equation 9:

Aᵣ=Aᵢ+H(f−f₀), (9)

where the drift coefficient H is set forth in Equation 10:

$$H = 2 π ( {T}_{r} - {T}_{i} ) - \frac{( {N}_{i} - 1 ) π}{{N}_{i} {f}_{0} } - \frac{( {N}_{r} - 1 ) π}{{N}_{r} {f}_{0} } , \qquad ( 10 )$$

Returning to FIG. 3, the communication module 355 may be configured to facilitate communication between the DMS 114 processor and the SMDs 118a, 118b, and 118c of FIG. 1 over the network 120 and to facilitate communication of control signals or messages to manage or control the operation of one or more components of the power system based on the SPAM data, including synchrophasor measurements, that have been collected from the SMDs 118a, 118b, and 118c and had their phase angles aligned.

Although FIG. 3 illustrates hardware/software architectures that may be used in data processing systems, such as the DMS 114 processor of FIG. 1 and the data processing system 200 of FIG. 2, respectively, for aligning phase angles of SPAM data generated by multiple SMDs, in accordance with some embodiments of the inventive concept it will be understood that the present invention is not limited to such a configuration but is intended to encompass any configuration capable of carrying out operations described herein.

Computer program code for carrying out operations of data processing systems discussed above with respect to FIGS. 1-3 may be written in a high-level programming language, such as Python, Java, C, and/or C++, for development convenience. In addition, computer program code for carrying out operations of the present invention may also be written in other programming languages, such as, but not limited to, interpreted languages. Some modules or routines may be written in assembly language or even micro-code to enhance performance and/or memory usage. It will be further appreciated that the functionality of any or all of the program modules may also be implemented using discrete hardware components, one or more application specific integrated circuits (ASICs), or a programmed digital signal processor or microcontroller.

Moreover, the functionality of the DMS 114 processor of FIG. 1, the data processing system 200 of FIG. 2, and the hardware/software architecture of FIG. 3, may each be implemented as a single processor system, a multi-processor system, a multi-core processor system, or even a network of stand-alone computer systems, in accordance with various embodiments of the inventive concept. Each of these processor/computer systems may be referred to as a “processor” or “data processing system.”

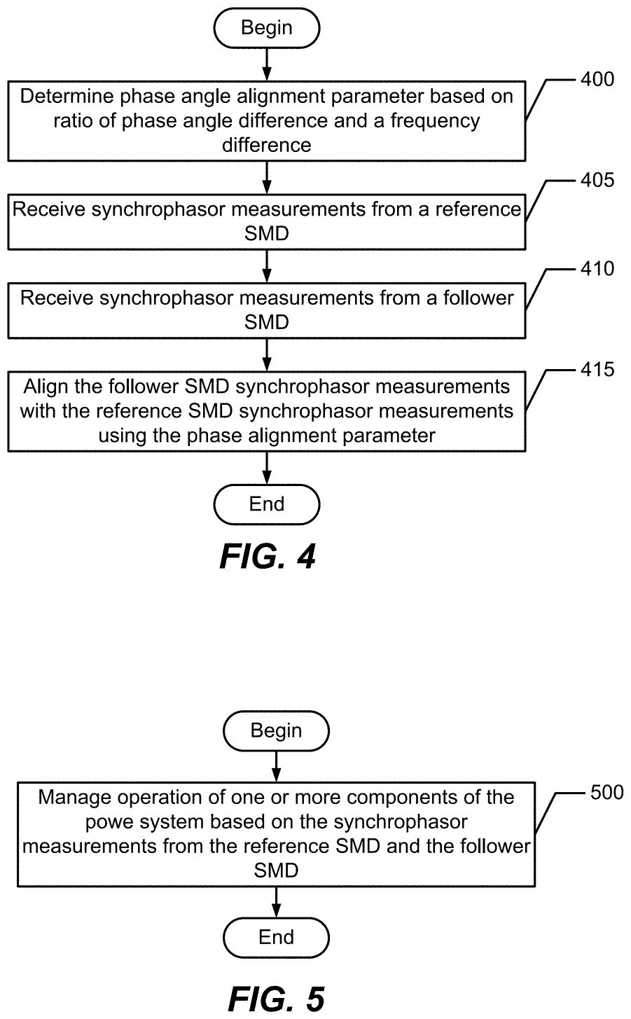

The data processing apparatus of FIGS. 1-3 may be used to facilitate the alignment of phase angles of SPAM data, including synchrophasor measurements, generated by multiple SMDs in a power system network, according to various embodiments described herein. These apparatus may be embodied as one or more enterprise, application, personal, pervasive and/or embedded computer systems and/or apparatus that are operable to receive, transmit, process and store data using any suitable combination of software, firmware and/or hardware and that may be standalone or interconnected by any public and/or private, real and/or virtual, wired and/or wireless network including all or a portion of the global communication network known as the Internet, and may include various types of tangible, non-transitory computer readable media. In particular, the memory 206 coupled to the processor 208 and the memory 305 coupled to the processor 300 include computer readable program code that, when executed by the respective processors, causes the respective processors to perform operations including one or more of the operations described herein with respect to FIGS. 4-10.

FIGS. 4-5 are flowcharts that illustrate operations for aligning phase angles of SPAM data generated by multiple SMDs in accordance with some embodiments of the inventive concept. Referring to FIG. 4, operations begin at block 400 where a phase angle alignment parameter or coefficient H may be determined based on a ration of a phase angle difference and a frequency difference. The phase angle difference may be a difference between a first phase angle corresponding to a reference or base SMD 118a, 118b, and 118c and the second phase angle may correspond to a follower SMD 118a, 118b, and 118c. The frequency difference may be a difference between a frequency at which the first and second phase angles are measured and a nominal frequency, e.g., 60 Hz. SPAM data including synchrophasor measurements are received from the reference SMD 118a, 118b, and 118c at block 405 and SPAM data including synchrophasor measurements are received from a follower SMD 118a, 118b, and 118c at block 410. These synchrophasor measurements between the two SMDs 118a, 118b, and 118c may be offset in time relative to each other by a sampling time shift. The phase angles of the synchrophasor measurements received from the follower SMD 118a, 118b, and 118c may be aligned with the phase angles of the synchrophasor measurements received from the reference SMD 118a, 118b, and 118c using the phase angle alignment parameter or coefficient H at block 415.

Referring to FIG. 5, the synchrophasor measurements that have been collected from the SMDs 118a, 118b, and 118c and had their phase angles aligned may be used to manage or control the operation of one or more components of the power system at block 500. For example, the phase angle aligned synchrophasor measurements may be used to detect events, such as droop, nominal frequency (e.g., 60 Hz) deviation based on load, islanding of portions of the power system, and the like and corrective or mitigating action may be taken to maintain the operational stability and improve the performance of the power system.

Example operations for determining the phase angle alignment parameter or coefficient H (block 400) and aligning phase angle measurements of a follower SMD 118a, 118b, and 118c with the phase angle measurements of a reference SMD 118a, 118b, and 118c, according to some embodiments of the inventive concept, will now be described.

Because H is related to Tr, Tf, Nr, and Nf, which are usually not available to the end user of an SMD 118a, 118b, and 118c, an experiment-based alignment method may be used to estimate the phase angle alignment parameter or coefficient H as follows:

First, connect the SMDs to a time synchronized signal generator and run the frequency ramp profile. The frequency ramp profile may start from the nominal frequency, e.g., 60 Hz, and end at the limits of the SMD measurement range, e.g., 2 Hz. In addition, the frequency slope may be a relatively low value to make sure both the SPAM data and frequencies are continuous. A slope of about 5.26 mHz/s may be used according to some embodiments of the inventive concept.

Second, record the SPAM data and frequency from all SMDs 118a, 118b, and 118c

and calculate the angle drifts between the reference and other SMDs.

Third, The aligned phase angle, Aaligned can be calculated as expressed in Equation 11:

A_{aligned}=A_{raw}+H(f−f₀), (11)

where the Araw is the raw phase angle. Hestimated can be calculated as set forth in Equation 12:

$${H}_{estimated} = \frac{{\sum }_{k = 1}^{N} \frac{{A}_{r , k} - {A}_{i , k}}{{f}_{k} - {f}_{0}}}{N} , \qquad ( 12 )$$

where Ar,k and Ai,k are the reference and the ith SMD's phase angles at time stamp k; N is the number of stamps.

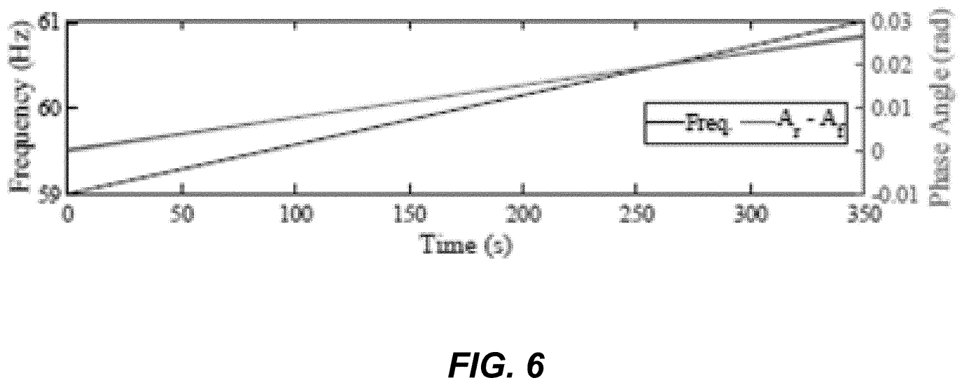

An example of applying the angle drift alignment method, according to some embodiments of the inventive concept, is provided to align two SMDs which use the same DFT algorithm with 1.7 ms sampling time shift. First, two SMDs are connected to a GPS-time synchronized signal generator (Omicron 256plus) running a frequency ramp profile and then the angle drifts are calculated as Ar−Af, shown in FIG. 6. The phase angle alignment parameter or coefficient Hk at each time step can be calculated through Equation 12. The phase angle alignment parameter or coefficient H is theoretically estimated as 0.0109 through Equation 10 while Hestimated can be calculated as 0.0118 by taking the average value of Hks in the experiment.

The phase angle alignment methodology, according to some embodiments of the inventive concept, can be applied in SMDs deployed in operating power systems to align the phase angles of the synchrophasor measurements included in the SPAM data. To verify the effectiveness of the phase angle alignment approach, according to some embodiments of the inventive concept, two SMDs with different FFT estimation algorithms are selected for alignment with a reference SMD in a laboratory. The detailed configurations for the SMDs are listed in Table I.

TABLE 1
SMD CONFIGURATION

| SMD | SPAM Algorithm | H_{estimated} |
|---|---|---|
| SMD₁ | Quasi-positive-sequence DFT in [8] | 0 |
| SMD₂ | Quasi-positive-sequence DFT in [8] | −0.42 |
| SMD₃ | Conventional DFT | 0.38 |

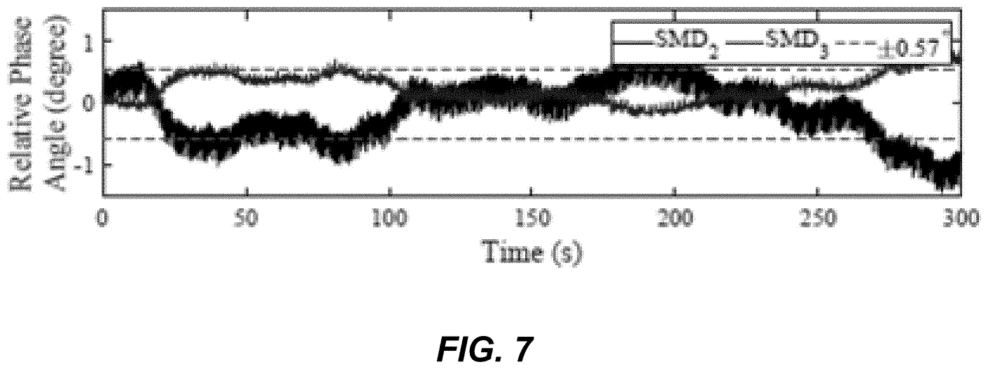

Among three SMDs, SMD₁ and SMD₂ use the same Quasi-positive-sequence DFT algorithm with different unknown time shift. The other SMD uses a conventional DFT algorithm. Note that SMD₁ is taken as the reference SMD. After running the frequency ramping profile, the H_{estimated} parameter of each SMD can be calculated via Equation 12 as listed in Table I. Then the SMDs under test are installed in a distribution level power grid. Before aligning their phase angles as described above in accordance with embodiments of the inventive concept, the relative phase angles between the SMD₁, SMD₂, and SMD₃ are shown in FIG. 7. It can be seen that there is a phase difference among these SMDs while most of the phase differences are within ±0.57°.

To eliminate the phase difference, the phase angles of the SPAM data can be corrected through Equation 11 using calculated H parameters in Table I. To quantify its effect, the relative phase angles are calculated set forth in Equation 13:

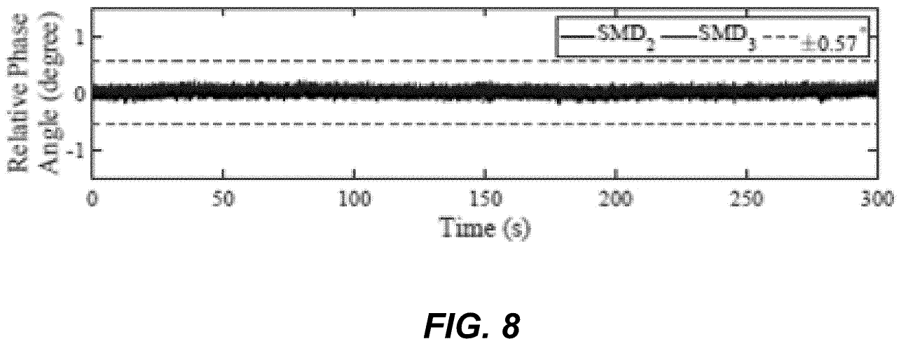

A_{relative,i,k}=A_{1,k}−A_{i,k} (13)

where k is the time stamp; A_{relative,i,k}, A_{1,k}, and A_{i,k} are the relative phase angle, phase angle of SMD₁, and phase angle of SMDᵢ. The relative phase angles after alignment according to some embodiments of the inventive concept are shown in FIG. 8. According to the results in Table II, both the mean and standard deviation (STD) of the aligned phase angles are significantly less than the raw phase angles.

TABLE II
FIELD TEST RESULTS (°)

| | Raw Angle | Raw Angle | Aligned Angle | Aligned Angle |
|---|---|---|---|---|
| SMD | Mean | STD | Mean | STD |
| SMD₂ | −0.0761 | 0.4560 | 0.0152 | 0.0889 |
| SMD₃ | 0.2522 | 0.2257 | 0.0740 | 0.0499 |

In addition to implementation in SMDs, the correction, i.e., alignment of phase angles from synchrophasor measurements contained in the SPAM data can also be performed in the PDC or other server. To verify the effectiveness of the SMD phase angle alignment embodiments described herein, phase angles were recorded for 10 minutes by six onsite SMDs deployed in an operational power grid in Puerto Rico (SMD₁ to SMD₅ use a same phase angle estimation algorithm while SMD₆ uses another algorithm) and were collected by a PDC.

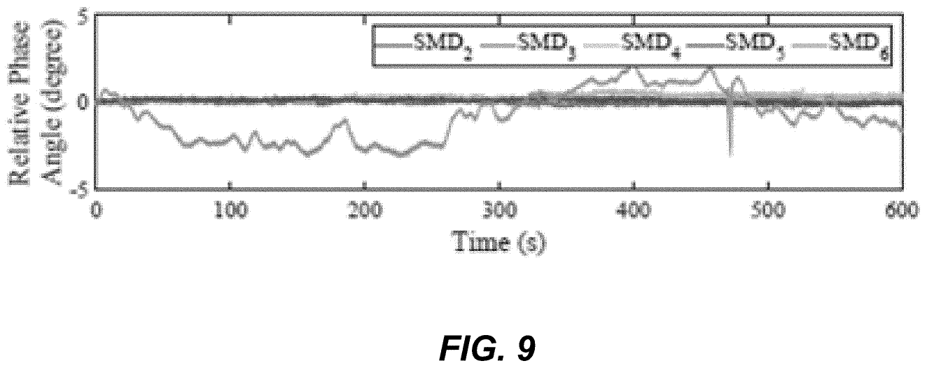

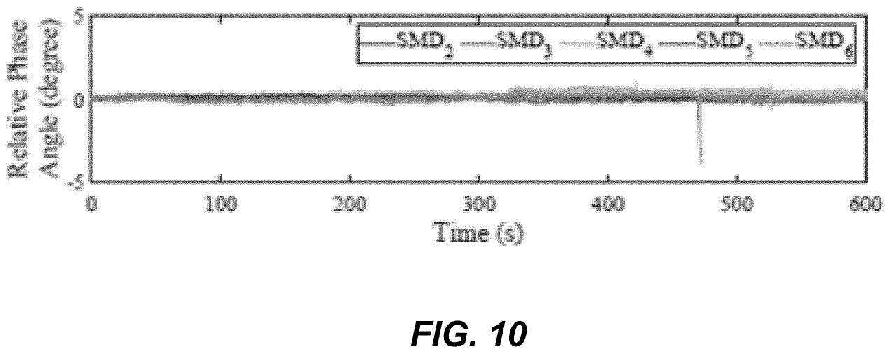

Since six SMDs are deployed in an area with a relatively small electrical distance, the relative phase angles should be close zero in ambient condition. FIG. 9 shows the relative phase angles for five SMDs (SMD₂ to SMD₆). Note that SMD₁ is taken as the reference. It can be viewed that SMD₆'s relative angle is unable to follow those of SMD₂ to SMD₅ due to the different SPAM estimation algorithms and presence of time shifts. To align the SPAM of SMD₆ with other SMDs, the alignment methodology, according to some embodiments of the inventive concept, as described herein is applied on the PDC. As shown in FIG. 10, the phase angle difference between SMD₆ and SMD₁ has been greatly reduced from 0.761° to 0.0643°.

SPAM data are widely used in a power system to improve the situational awareness of the operational state of the power system. Practical time drift can lead to unexpected phase angle difference between measurements collected from different SMDs that may be manufactured by different vendors. Because most vendors of SMDs estimate the phase angle via DFT based approaches, the phase angle deviation may become worse under off-nominal frequency conditions. Embodiments of the inventive concept may provide a methodology to determine a phase angle alignment parameter experimentally based on a ration of a phase angle difference and a frequency difference where the phase angle difference corresponds to a difference between a first phase angle corresponding to a reference SMD and a second phase angle corresponding to a follower SMD. The frequency difference may be a difference between a frequency at which the first and second phase angles are measured and a nominal frequency. The phase angle alignment parameter may be used to align phase angles included in the SPAM data of a follower SMD with those of a reference SMD.

### Further Definitions and Embodiments

In the above-description of various embodiments of the present disclosure, aspects of the present disclosure may be illustrated and described herein in any of a number of patentable classes or contexts including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “circuit,” “module,” “component,” or “system.” Furthermore, aspects of the present disclosure may take the form of a computer program product comprising one or more computer readable media having computer readable program code embodied thereon.

Any combination of one or more computer readable media may be used. The computer readable media may be a computer readable signal medium or a computer readable storage medium. A computer readable storage medium may be, for example, but not limited to, an electronic, magnetic, optical, electromagnetic, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), an appropriate optical fiber with a repeater, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB.NET, Python or the like, conventional procedural programming languages, such as the “C” programming language, Visual Basic, Fortran 2003, Perl, COBOL 2002, PHP, ABAP, LabVIEW, dynamic programming languages, such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable instruction execution apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

The flowchart and block diagrams in the figures illustrate the architecture, functionality, and operation of possible implementations of systems, methods, and computer program products according to various aspects of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular aspects only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Like reference numbers signify like elements throughout the description of the figures.

The present disclosure of embodiments has been presented for purposes of illustration and description, but is not intended to be exhaustive or limited to the disclosure in the form disclosed. Many variations and modifications can be made to the embodiments without substantially departing from the principles of the present invention. All such variations and modifications are intended to be included herein within the scope of the present invention.

What is claimed is:

1. A method comprising:
performing by a processor:
determining a phase angle alignment parameter based on a ratio of a phase angle difference and a frequency difference, the phase angle difference comprising a difference between a first phase angle corresponding to a reference synchronized measurement device (SMD) and a second phase angle corresponding to a follower SMD, the frequency difference comprising a difference between a frequency at which the first and second phase angles are measured and a nominal frequency;
receiving a first plurality of synchrophasor measurements of a power system signal from the reference SMD;
receiving a second plurality of synchrophasor measurements of the power system signal from the follower SMD, the first plurality of synchrophasor measurements and the second plurality of synchrophasor measurements being offset in time relative to each other by a sampling time shift; and
aligning phase angles of the second plurality of synchrophasor measurements with phase angles of the first plurality of synchrophasor measurements using the phase angle alignment parameter.

2. The method of claim 1, wherein determining the phase angle alignment parameter comprises:
averaging the ratio of the phase angle difference and the frequency difference over a plurality of frequencies at which the first and second phase angles are measured.

3. The method of claim 2, wherein the plurality of frequencies are in a range between the nominal frequency and the nominal frequency plus 2 Hz.

4. The method of claim 1, wherein the nominal frequency is about 60 Hz.

5. The method of claim 1, wherein a manufacturer of the reference SMD is different than a manufacturer of the follower SMD.

6. The method of claim 1, wherein aligning phase angles of the second plurality of synchrophasor measurements with phase angles of the first plurality of synchrophasor measurements comprises:
determining an offset for each of the second plurality of synchrophasor measurements, the offset comprising a product of the phase angle alignment parameter and a difference between a frequency corresponding to the respective one of the second plurality of synchrophasor measurements and the nominal frequency; and
adding the plurality of offsets to the phase angles of the second plurality of synchrophasor measurements, respectively.

7. The method of claim 1, further comprising:
managing operation of one or more components of the power system based on the first plurality of synchrophasor measurements from the reference SMD and the second plurality of synchrophasor measurements from the follower SMD.

8. A system, comprising:
a processor; and
a memory coupled to the processor and comprising computer readable program code embodied in the memory that is executable by the processor to perform operations comprising:
determining a phase angle alignment parameter based on a ratio of a phase angle difference and a frequency difference, the phase angle difference comprising a difference between a first phase angle corresponding to a reference synchronized measurement device (SMD) and a second phase angle corresponding to a follower SMD, the frequency difference comprising a difference between a frequency at which the first and second phase angles are measured and a nominal frequency;
receiving a first plurality of synchrophasor measurements of a power system signal from the reference SMD;
receiving a second plurality of synchrophasor measurements of the power system signal from the follower SMD, the first plurality of synchrophasor measurements and the second plurality of synchrophasor measurements being offset in time relative to each other by a sampling time shift; and
aligning phase angles of the second plurality of synchrophasor measurements with phase angles of the first plurality of synchrophasor measurements using the phase angle alignment parameter.

9. The system of claim 8 wherein determining the phase angle alignment parameter comprises:
averaging the ratio of the phase angle difference and the frequency difference over a plurality of frequencies at which the first and second phase angles are measured.

10. The system of claim 9, wherein the plurality of frequencies are in a range between the nominal frequency and the nominal frequency plus 2 Hz.

11. The system of claim 8, wherein the nominal frequency is about 60 Hz.

12. The system of claim 8, wherein a manufacturer of the reference SMD is different than a manufacturer of the follower SMD.

13. The system of claim 8, wherein aligning phase angles of the second plurality of synchrophasor measurements with phase angles of the first plurality of synchrophasor measurements comprises:
determining an offset for each of the second plurality of synchrophasor measurements, the offset comprising a product of the phase angle alignment parameter and a difference between a frequency corresponding to the respective one of the second plurality of synchrophasor measurements and the nominal frequency; and
adding the plurality of offsets to the phase angles of the second plurality of synchrophasor measurements, respectively.

14. The system of claim 8, wherein the operations further comprise:
managing operation of one or more components of the power system based on the first plurality of synchrophasor measurements from the reference SMD and the second plurality of synchrophasor measurements from the follower SMD.

15. A computer program product, comprising:
a non-transitory computer readable storage medium comprising computer readable program code embodied in the medium that is executable by a processor to perform operations comprising:
determining a phase angle alignment parameter based on a ratio of a phase angle difference and a frequency difference, the phase angle difference comprising a difference between a first phase angle corresponding to a reference synchronized measurement device (SMD) and a second phase angle corresponding to a follower SMD, the frequency difference comprising a difference between a frequency at which the first and second phase angles are measured and a nominal frequency;
receiving a first plurality of synchrophasor measurements of a power system signal from the reference SMD;
receiving a second plurality of synchrophasor measurements of the power system signal from the follower SMD, the first plurality of synchrophasor measurements and the second plurality of synchrophasor measurements being offset in time relative to each other by a sampling time shift; and
aligning phase angles of the second plurality of synchrophasor measurements with phase angles of the first plurality of synchrophasor measurements using the phase angle alignment parameter.

16. The computer program product of claim 15, wherein determining the phase angle alignment parameter comprises:
averaging the ratio of the phase angle difference and the frequency difference over a plurality of frequencies at which the first and second phase angles are measured.

17. The computer program product of claim 16, wherein the plurality of frequencies are in a range between the nominal frequency and the nominal frequency plus 2 Hz.

18. The computer program product of claim 15, wherein the nominal frequency is about 60 Hz.

19. The computer program product of claim 15, wherein aligning phase angles of the second plurality of synchrophasor measurements with phase angles of the first plurality of synchrophasor measurements comprises:
determining an offset for each of the second plurality of synchrophasor measurements, the offset comprising a product of the phase angle alignment parameter and a difference between a frequency corresponding to the respective one of the second plurality of synchrophasor measurements and the nominal frequency; and
adding the plurality of offsets to the phase angles of the second plurality of synchrophasor measurements, respectively.

20. The computer program product of claim 15, wherein the operations further comprise:
managing operation of one or more components of the power system based on the first plurality of synchrophasor measurements from the reference SMD and the second plurality of synchrophasor measurements from the follower SMD.
